(19) United States
(12) Patent Application Publication
(10) Pub. No.: US 2025/0199137 A1
(43) Pub. Date: Jun. 19, 2025

(54) PHOTODETECTOR AND DISTANCE MEASUREMENT APPARATUS

(71) Applicant: SONY SEMICONDUCTOR SOLUTIONS CORPORATION, Kanagawa (JP)

(72) Inventor: Fumiaki SANO, Kanagawa (JP)

(73) Assignee: SONY SEMICONDUCTOR SOLUTIONS CORPORATION, Kanagawa (JP)

(21) Appl. No.: 18/847,766

(22) PCT Filed: Feb. 10, 2023
(86) PCT No.: PCT/JP2023/004583

§ 371 Date: Sep. 17, 2024

(30) Foreign Application Priority Data
Apr. 6, 2022 (JP) 2022-063649

(51) Int. Cl. G01S 7/4863; G01S 7/481; G01S 17/10

(52) U.S. Cl. CPC G01S 7/4863; G01S 7/4816; G01S 17/10

(57) ABSTRACT

A photodetector and distance measurement apparatus are provided. The photodetector includes a pixel array, a semi-conductor substrate, and a pixel isolation section. The pixel isolation section is disposed in the semiconductor substrate and surrounds unit pixels of the pixel array in the plan view. A first unit pixel of the plurality of unit pixels includes a light receiving section disposed within an area formed by the pixel isolation section surrounding the first unit pixel in the plan view, a first electrode disposed within the area formed by the pixel isolation section surrounding the first unit pixel in the plan view, and a second electrode disposed within an area of the light receiving section. The first and second electrodes are disposed along a line that is oblique relative to rows and columns of the unit pixels of the pixel array.

### CROSS REFERENCE TO RELATED APPLICATIONS

This application claims the benefit of Japanese Priority Patent Application JP 2022-063649 filed Apr. 6, 2022, the entire contents of which are incorporated herein by reference.

### TECHNICAL FIELD

The present disclosure relates, for example, to a photodetector in which an avalanche photodiode is used, a distance measurement apparatus, and an imaging apparatus.

### BACKGROUND ART

For example, PTL 1 discloses a photoelectric conversion apparatus in which an anode electrode is disposed in a middle of a pixel having a rectangular shape and cathode electrodes are disposed at four corners of the pixel having a rectangular shape.

### CITATION LIST

### Patent Literature

PTL 1: JP 2021-34559

### SUMMARY

### Technical Problem

Incidentally, a photodetector included in a distance measurement apparatus has an issue with occurrence of edge breakdown.

It is desirable to provide a photodetector that makes it possible to reduce occurrence of edge breakdown, a distance measurement apparatus, and an imaging apparatus.

### Solution to Problem

A photodetector according to an embodiment of the present disclosure includes: a semiconductor substrate; a light-receiving section; a multiplication section; a first electrode; and a second electrode. The semiconductor substrate has a first surface and a second surface that are opposed to each other. The semiconductor substrate includes a pixel array unit in which a plurality of pixels is disposed in an array in a row direction and a column direction. The light-receiving section is provided in the semiconductor substrate for each of the pixels, the light-receiving section generating a carrier through photoelectric conversion. The carrier corresponds to an amount of received light. The multiplication section includes a first semiconductor region and a second semi-conductor region that are stacked on the first surface side of the semiconductor substrate for each of the pixels. The first semiconductor region has a first electrical conduction type. The second semiconductor region has a second electrical conduction type different from the first electrical conduction type. The multiplication section subjects the carrier generated by the light-receiving section to avalanche multiplication. The first electrode is disposed for each of the pixels in an oblique direction from a middle of the pixel on the first surface side of the semiconductor substrate. The first electrode is electrically coupled to the light-receiving section independently for each of the pixels. The second electrode is disposed for each of the pixels substantially in the middle of the pixel on the first surface side of the semiconductor substrate. The second electrode is electrically coupled to the multiplication section independently for each of the pixels.

A distance measurement apparatus according to an embodiment of the present disclosure includes an optical system, a photodetector, and a signal processing circuit that calculates a distance to a measurement target from an output signal of the photodetector. The distance measurement apparatus includes, as the photodetector, the photodetector according to the embodiment of the present disclosure described above.

An imaging apparatus according to an embodiment of the present disclosure includes the photodetector according to the embodiment of the present disclosure described above.

In the photodetector according to the embodiment of the present disclosure, the distance measurement apparatus according to the embodiment, and the imaging apparatus according to the embodiment, in each of the plurality of pixels disposed in the array in the row direction and the column direction, the first electrode is disposed in the oblique direction from the middle of the pixel on the first surface side of the semiconductor substrate and the second electrode is disposed substantially in the middle of the pixel on the first surface side of the semiconductor substrate. The first electrode is electrically coupled to the light-receiving section. The second electrode is electrically coupled to the multiplication section. This secures a distance between the first electrode and the second electrode and makes an electric field in a lateral direction smaller.

### BRIEF DESCRIPTION OF DRAWINGS

FIG. 1 is a plane schematic diagram illustrating a configuration of a photodetector according to an embodiment of the present disclosure.

FIG. 2 is a block diagram illustrating an example of a schematic configuration of the photodetector illustrated in FIG. 1.

FIG. 3 is an example of an equivalent circuit diagram of a unit pixel of the photodetector illustrated in FIG. 1.

FIG. 4 is a plane schematic diagram in which another component is added to the photodetector illustrated in FIG. 1.

FIG. 5 is a cross-sectional schematic diagram of a unit pixel of the photodetector illustrated in FIG. 1 corresponding to an I-I line.

FIG. 6 is a schematic diagram illustrating an example of a cross-sectional configuration of the unit pixel of any of the photodetectors illustrated in FIGS. 1 and 4 corresponding to an II-II line and an III-III line.

FIG. 7 is a schematic diagram illustrating another example of the cross-sectional configuration of the unit pixel of any of the photodetectors illustrated in FIGS. 1 and 4 corresponding to the II-II line and the III-III line.

FIG. 8 is a plane schematic diagram illustrating a configuration of a photodetector according to a modification example 1 of the present disclosure.

FIG. 9 is a cross-sectional schematic diagram of a unit pixel of the photodetector illustrated in FIG. 8 corresponding to an IV-IV line.

FIG. 10 is a plane schematic diagram illustrating a configuration of a photodetector according to a modification example 2 of the present disclosure.

FIG. 11 is a cross-sectional schematic diagram of a unit pixel of the photodetector illustrated in FIG. 10.

FIG. 12 is a plane schematic diagram illustrating a configuration of a photodetector according to a modification example 3 of the present disclosure.

FIG. 13 is a cross-sectional schematic diagram of a unit pixel of the photodetector illustrated in FIG. 12.

FIG. 14 is a cross-sectional schematic diagram illustrating a configuration of a photodetector according to a modification example 4 of the present disclosure.

FIG. 15 is a plane schematic diagram illustrating a configuration of a photodetector according to a modification example 5 of the present disclosure.

FIG. 16 is a cross-sectional schematic diagram of a unit pixel of the photodetector illustrated in FIG. 15.

FIG. 17 is a cross-sectional schematic diagram illustrating a configuration of a photodetector according to a modification example 6 of the present disclosure.

FIG. 18 is a cross-sectional schematic diagram illustrating a configuration of a photodetector according to a modification example 7 of the present disclosure.

FIG. 19 is a functional block diagram illustrating an example of an electronic apparatus in which the photodetector illustrated in FIG. 1 or the like is used.

FIG. 20 is a block diagram illustrating an example of a configuration of an imaging apparatus in which the photodetector illustrated in FIG. 1 or the like is used.

FIG. 21 is a block diagram depicting an example of schematic configuration of a vehicle control system.

FIG. 22 is a diagram of assistance in explaining an example of installation positions of an outside-vehicle information detecting section and an imaging section.

### DESCRIPTION OF EMBODIMENTS

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.
1. Embodiment (a photodetector in which a cathode electrode is disposed substantially in a middle of a pixel and an anode electrode is disposed in an oblique direction from the middle of the pixel)
1-1. Configuration of Photodetector
1-2. Workings and Effects
2. Modification Examples
2-1. Modification Example 1 (an example in which an electrode isolation section is provided between an anode electrode and a cathode electrode)
2-2. Modification Example 2 (an example in which an optical reflection film is buried in a pixel isolation section and an electrode isolation section)
2-3. Modification Example 3 (an example in which an optical reflection film is formed by using an electrically conductive material)
2-4. Modification Example 4 (an example in which an optical reflection film is formed by using an electrically conductive material)
2-5. Modification Example 5 (an example in which a light-shielding film is provided at a position overlapping with an anode electrode in a plan view on a light incidence surface side)
2-6. Modification Example 6 (an example in which p-type and n-type semiconductor regions are provided on side surfaces of a pixel isolation section and an electrode isolation section corresponding to a multiplication section)
2-7. Modification Example 7 (an example in which a metal film is buried in a semi-conductor substrate as an anode electrode)
3. Application Examples
4. Practical Application Example

### 1. Embodiment

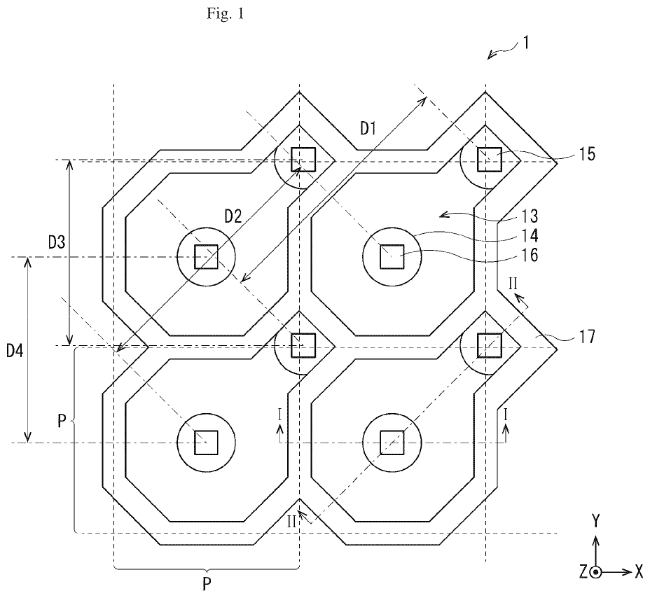

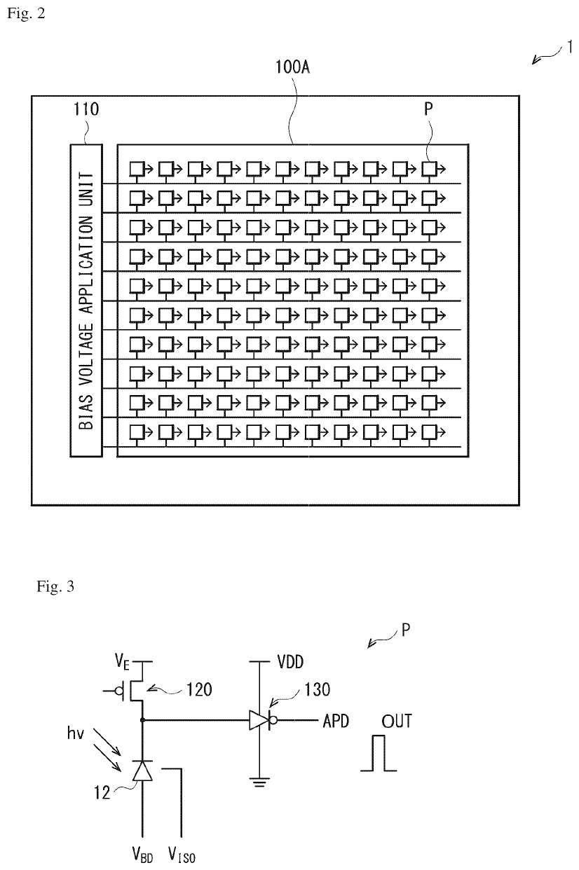

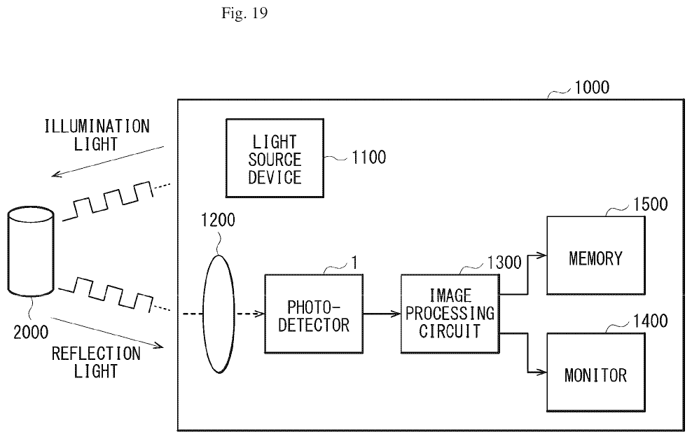

FIG. 1 schematically illustrates a planar configuration of a photodetector (photodetector 1) according to an embodiment of the present disclosure. FIG. 2 is a block diagram illustrating a schematic configuration of the photodetector 1 illustrated in FIG. 1. FIG. 3 illustrates an example of an equivalent circuit of a unit pixel P of the photodetector 1 illustrated in FIG. 1. The photodetector 1 is applied, for example, to a distance measurement apparatus (a distance image apparatus 1000 described below with reference to FIG. 19), a light detecting device, an image sensor, or the like that measures a distance in a Time-of-Flight (ToF) method.

### 1-1. Configuration of Photodetector

The photodetector 1 includes a pixel array unit 100A in which the plurality of unit pixels P each having, for example, a polygonal shape or a circular shape is disposed in an array in a row direction and a column direction. As illustrated in FIG. 2, the photodetector 1 includes a bias voltage application unit 110 along with the pixel array unit 100A. The bias voltage application unit 110 applies a bias voltage to each of the unit pixels P in the pixel array unit 100A. In the present embodiment, a case where electrons are read out as signal charge is described.

As illustrated in FIG. 3, the unit pixel P includes a light-receiving element 12, a quenching resistance element 120, and an inverter 130. The quenching resistance element 120 includes a p-type Metal-Oxide-Semiconductor Field-Effect Transistor (MOSFET). The inverter 130 includes, for example, complementary MOSFET.

The light-receiving element 12 converts incident light into an electric signal through photoelectric conversion. The light-receiving clement 12 outputs the electric signal. Incidentally, the light-receiving element 12 converts incident light (photon) into an electric signal through photoelectric conversion. The light-receiving element 12 outputs a pulse corresponding to an incident photon. The light-receiving element 12 is, for example, a Single Photon Avalanche Diode (SPAD) element. The SPAD clement forms an avalanche multiplication region 12X (depletion layer), for example, by having a large negative voltage applied to a cathode. The SPAD clement has characteristics that electrons generated by a single incident photon cause avalanche multiplication and cause a large current to flow. For example, an anode of the light-receiving element 12 is coupled to the bias voltage application unit 110 and the cathode of the light-receiving element 12 is coupled to a source terminal of the quenching resistance element 120. The bias voltage application unit 110 applies a bias voltage V_{BD} to the anode of the light-receiving element 12.

The quenching resistance element 120 is coupled to the light-receiving element 12 in series. The source terminal of the quenching resistance element 120 is coupled to the cathode of the light-receiving element 12 and a drain terminal of the quenching resistance element 120 is coupled to an unillustrated power supply. The power supply applies an excitation voltage V_{E} to the drain terminal of the quenching resistance element 120. In a case where a voltage resulting from electrons subjected to avalanche multiplication in the light-receiving element 12 reaches the negative voltage V_{BD}, the quenching resistance element 120 performs quenching to discharge the electrons multiplied by the light-receiving element 12 and restore the voltage to an initial voltage.

An input terminal of the inverter 130 is coupled to the cathode of the light-receiving element 12 and the source terminal of the quenching resistance element 120 and an output terminal of the inverter 130 is coupled to an unillustrated subsequent arithmetic processing section. The inverter 130 outputs a light reception signal on the basis of carriers (signal charge) multiplied by the light-receiving clement 12. More specifically, the inverter 130 shapes the voltage generated by the electrons multiplied by the light-receiving element 12. The inverter 130 then outputs a light reception signal (APD OUT) to the arithmetic processing section. The light reception signal (APD OUT) has a pulse waveform illustrated, for example, in FIG. 3 with an arrival time of a single photon as a start point. For example, the arithmetic processing section performs arithmetic processing for obtaining distances to an object on the basis of timings of occurrences of the pulses in respective light reception signals and obtains the distances for the respective unit pixels P. The occurrence of the pulse indicates the arrival time of a single photon. A distance image is then generated on the basis of those distances. In the distance image, the distances to the object detected by the plurality of respective unit pixels P are arranged in a planar manner.

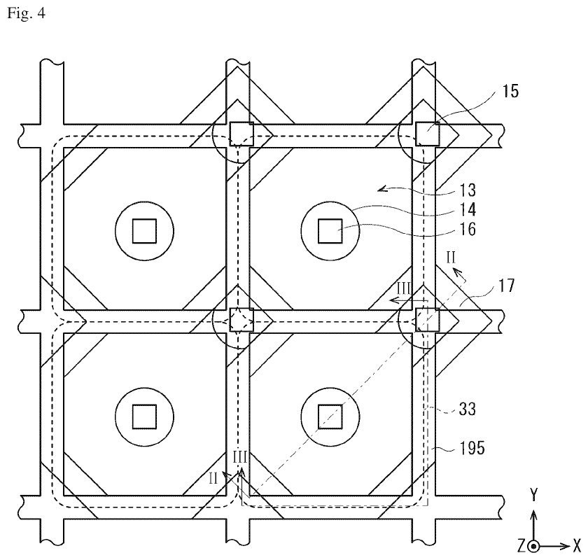

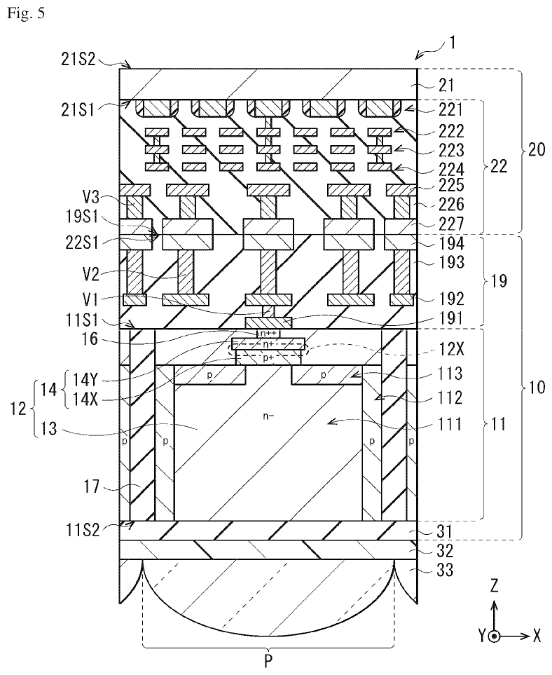

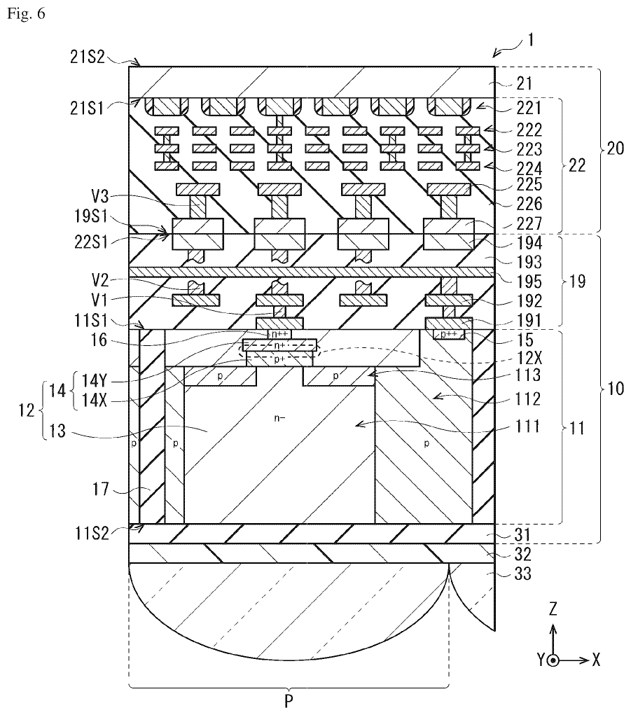

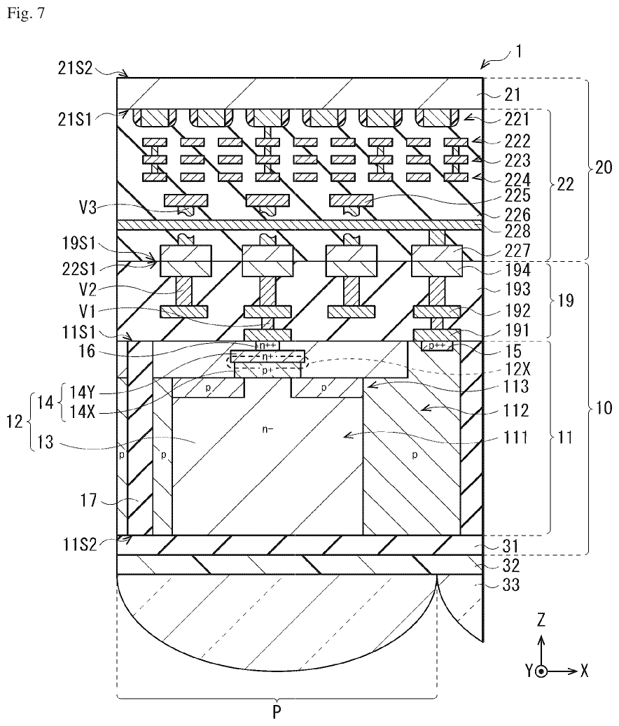

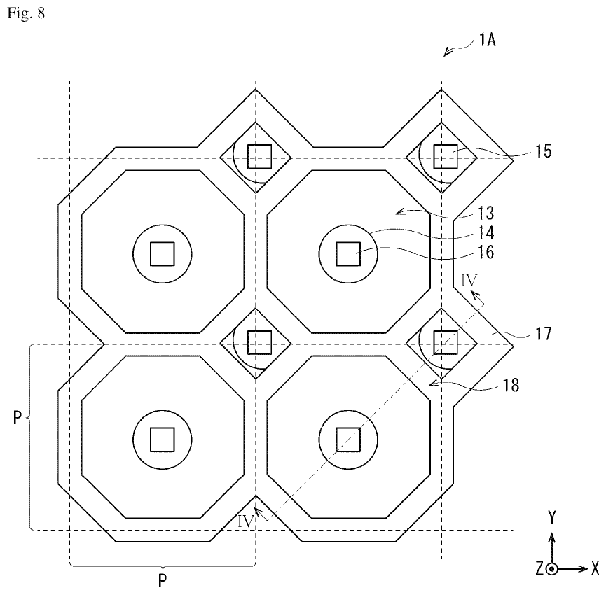

FIG. 4 is a plane schematic diagram in which another component is added to the photodetector 1 illustrated in FIG. 1. FIG. 5 illustrates a cross-sectional configuration of the unit pixel P of the photodetector 1 illustrated in FIG. 1 corresponding to an I-I line. FIG. 6 illustrates an example of a cross-sectional configuration of the unit pixel P of the photodetector 1 illustrated in FIG. 1 corresponding to an II-II line and an III-III line. FIG. 7 illustrates another example of the cross-sectional configuration of the unit pixel P of the photodetector 1 illustrated in FIG. 1 corresponding to the II-II line and the III-III line. The photodetector 1 is a so-called back-illuminated photodetector that has a logic board 20 stacked, for example, on a front surface side (e.g., a front surface (first surface 11S1) side of a semiconductor substrate 11 included in a sensor board 10) of the sensor board 10 and receives light from a back surface side (e.g., a back surface (second surface 11S2) of the semiconductor substrate 11 included in the sensor board 10) of the sensor board 10.

The photodetector 1 includes the light-receiving element 12 for each of the unit pixels P. The light-receiving element 12 includes a light-receiving section 13 and a multiplication section 14. The light-receiving section 13 and the multiplication section 14 are formed to be buried, for example, in the semiconductor substrate 11. The semiconductor substrate 11 further includes a pixel isolation section 17. The pixel isolation section 17 is provided around the unit pixels P to extend between the first surface 11S1 and the second surface 11S2. The pixel isolation section 17 electrically isolates the adjacent unit pixels P. In the photodetector 1, the plurality of unit pixels P each having a polygonal shape or a circular shape as described above is disposed in an array in the row direction and the column direction. In the present embodiment, the technology is described by using, as an example, a case where the unit pixels P each have an octagonal shape.

The plurality of unit pixels P each includes an anode electrode 15 and a cathode electrode 16 each on the first surface 11S1 side of the semiconductor substrate 11. The anode electrode 15 is electrically coupled to the light-receiving section 13 independently for each of the unit pixel P. The cathode electrode 16 is electrically coupled to the multiplication section 14. The anode electrode 15 is disposed in an oblique direction from a middle of the unit pixel P. The cathode electrode 16 is disposed substantially in the middle of the unit pixel P. Specifically, the anode electrode 15 is disposed in a gap between the unit pixels P adjacent in the oblique direction (e.g., a 45° direction). The gap is generated by disposing, in a matrix, the unit pixels P each having an octagonal shape. The cathode electrode 16 is disposed substantially in the middle of the unit pixel P having an octagonal shape.

It is to be noted that symbols “p” and “n” in the diagram respectively represent a p-type semiconductor region and an n-type semiconductor region. Further, “+” or “−” at an end of “p” indicates an impurity concentration of the p-type semiconductor region. Similarly, “+” or “−” at an end of “n” indicates an impurity concentration of the n-type semiconductor region. Here, the semiconductor regions having more “+” each have a higher impurity concentration and the semiconductor regions having more “−” each have a lower impurity concentration. The same applies to the drawings described below.

The sensor board 10 includes, for example, the semiconductor substrate 11 and a multilayer wiring layer 19. The semiconductor substrate 11 includes a silicon substrate. The semiconductor substrate 11 has the first surface 11S1 and the second surface 11S2 that are opposed to each other. The semiconductor substrate 11 includes an n-type semiconductor region (n⁻) 111 for each of the unit pixels P. The n-type semiconductor region (n⁻) 111 is included in the light-receiving section 13. The n-type semiconductor region (n⁻) 111 is controlled, for example, to have an n-type impurity concentration. The semiconductor substrate 11 further includes a p-type semiconductor region (p⁺) 14X and an n-type semiconductor region (n⁺) 14Y included in the multiplication section 14 on the first surface 11S1 side. This forms the light-receiving element 12 for each of the unit pixels P.

The pixel isolation section 17 is provided around the unit pixels P. The pixel isolation section 17 electrically isolates the adjacent unit pixels P from each other. There is provided a p-type semiconductor region (p) 112 on a side surface of the pixel isolation section 17 corresponding to the light-receiving section 13. The p-type semiconductor region (p) 112 is controlled, for example, to have a p-type impurity concentration. A portion of this p-type semiconductor region (p) 112 extends to a region around the anode electrode 15. A p-type semiconductor region (p) 113 extends in the semiconductor substrate 11, for example, in contact with a region from a side surface of the p-type semiconductor region (p) 112 on the first surface 11S1 side to a portion of a surface of the p-type semiconductor region (p⁺) 14X on the second surface 11S2 side to couple the p-type semiconductor region (p) 112 and the p-type semiconductor region (p⁺) 14X. The p-type semiconductor region (p) 112 is selectively provided on the side surface of the pixel isolation section 17 corresponding to the light-receiving section 13. The p-type semiconductor region (p⁺) 14X is included in the multiplication section 14.

The light-receiving element 12 includes a multiplication region (avalanche multiplication region 12X) in which carriers are subjected to avalanche multiplication by a high electric field region. The light-receiving element 12 is an SPAD element that forms the avalanche multiplication region 12X by having a large negative voltage applied to the cathode electrode 16 as described above and makes it possible to subject electrons generated by a single incident photon to avalanche multiplication.

The light-receiving element 12 includes the light-receiving section 13 and the multiplication section 14.

The light-receiving section 13 corresponds to a specific example of a “light-receiving section” according to an embodiment of the present disclosure. The light-receiving section 13 has photoelectric conversion functions of absorbing light coming from the second surface 11S2 side of the semiconductor substrate 11 and generating carriers corresponding to the amount of received light. As described above, the light-receiving section 13 includes the n-type semiconductor region (n) 111 that is controlled to have an n-type impurity concentration. The carriers (electrons) generated by the light-receiving section 13 are transferred to the multiplication section 14 by a potential gradient.

The multiplication section 14 corresponds to a specific example of a “multiplication section” according to an embodiment of the present disclosure. The multiplication section 14 subjects the carriers (electrons here) generated by the light-receiving section 13 to avalanche multiplication. The multiplication section 14 includes, for example, the p-type semiconductor region (p⁺) 14X and the n-type semiconductor region (n⁺) 14Y. The n-type semiconductor region (n⁺) 14Y has a higher impurity concentration than that of the n-type semiconductor region (n) 111. The p-type semiconductor region (p⁺) 14X and the n-type semiconductor region (n⁺) 14Y are provided on the first surface 11S1 side. The n-type semiconductor region (n⁺) 14Y and the p-type semiconductor region (p⁺) 14X are stacked in this order from the first surface 11S1 side.

In the light-receiving element 12, the avalanche multiplication region 12X is formed at a position at which the p-type semiconductor region (p⁺) 14X and the n-type semi-conductor region (n⁺) 14Y are joined. The avalanche multiplication region 12X is a high electric field region (depletion layer) that is formed on a boundary surface between the p-type semiconductor region (p⁺) 14X and the n-type semiconductor region (n⁺) 14Y by the large negative voltage applied to the cathode. The avalanche multiplication region 12X multiplies electrons (e⁻) generated by a single photon entering the light-receiving element 12.

The anode electrode 15 and the cathode electrode 16 are further formed to be buried in the first surface 11S1 of the semiconductor substrate 11. The anode electrode 15 includes a p-type semiconductor region (p⁺⁺) that is electrically coupled to the n-type semiconductor region (n) 111 through the p-type semiconductor region (p) 112. The n-type semiconductor region (n) 111 is included in the light-receiving section 13. The cathode electrode 16 includes an n-type semiconductor region (n⁺⁺) that is electrically coupled to the n-type semiconductor region (n⁺) 14Y included in the multiplication section 14. The anode electrode 15 corresponds to a specific example of a “first electrode” according to an embodiment of the present disclosure. The cathode electrode 16 corresponds to a specific example of a “second electrode” according to an embodiment of the present disclosure.

In the present embodiment, the anode electrodes 15 in the plurality of unit pixels P disposed in a matrix, for example, as illustrated in FIG. 1 are each disposed between the cathode electrodes 16 provided in the respective unit pixels P adjacent, for example, in the oblique direction. In addition, for example, as illustrated in FIG. 1, in the plurality of unit pixels P disposed in a matrix, the anode electrodes 15 and the cathode electrodes 16 are disposed to equalize a distance D1 between the anode electrodes 15 provided in the respective unit pixels P adjacent, for example, in the oblique direction and a distance D2 between the cathode electrodes 16 provided in the respective unit pixels P adjacent, for example, in the oblique direction. Further, for example, as illustrated in FIG. 1, the anode electrodes 15 and the cathode electrodes 16 are disposed to equalize a distance D3 between the anode electrodes 15 provided in the respective unit pixels P adjacent in the row direction (X axis direction) and the column direction (Y axis direction) and a distance D4 between the cathode electrodes 16 provided in the respective unit pixels P adjacent in the row direction (X axis direction) and the column direction (Y axis direction).

The pixel isolation section 17 electrically isolates the adjacent unit pixels P. The pixel isolation section 17 is provided to surround each of the plurality of unit pixels P, for example, in a plan view. Specifically, the pixel isolation section 17 is provided to surround the unit pixels P (light-receiving sections 13) each having an octagonal shape and the anode electrodes 15 disposed in the gaps between the unit pixels P adjacent in the oblique direction (e.g., the 45° direction). The pixel isolation section 17 extends between the first surface 11S1 and the second surface 11S2 of the semiconductor substrate 11. For example, the pixel isolation section 17 penetrates the semiconductor substrate 11. The pixel isolation section 17 is formed by using, for example, an insulating film such as a silicon oxide (SiOₓ) film.

The multilayer wiring layer 19 is provided on the first surface 11S1 side of the semiconductor substrate 11. In the multilayer wiring layer 19, wiring layers 191 and 192 are formed in an interlayer insulating layer 193. Each of the wiring layers 191 and 192 includes one or more wiring lines. Each of the wiring layers 191 and 192 is, for example, for supplying a voltage to be applied to the semiconductor substrate 11 or the light-receiving element 12 and extracting a carrier generated by the light-receiving clement 12. A portion of the wiring lines in the wiring layer 191 is electrically coupled to the anode electrode 15 or the cathode electrode 16. A plurality of pad electrodes 194 is buried in a front surface (a front surface 19S1 of the multilayer wiring layer 19) of the interlayer insulating layer 193 opposite to the semiconductor substrate 11 side. The plurality of pad electrodes 194 is electrically coupled to portions of the wiring lines in the wiring layers 191 and 192 through a via V1 and a via V2.

There may be further provided a wiring layer 195 in the multilayer wiring layer 19. The wiring layer 195 electrically couples the anode electrodes 15 provided in the plurality of respective unit pixels P. For example, as illustrated in FIG. 4, the wiring layer 195 is provided in a lattice shape in the plane of the pixel array unit 100A.

The wiring layers 191, 192, and 195 are each formed by using, for example, aluminum (Al), copper (Cu), tungsten (W), or the like.

The interlayer insulating layer 193 includes, for example, a monolayer film including one of silicon oxide (SiOₓ), TEOS, silicon nitride (SiNₓ), silicon oxynitride (SiOₓN_{y}), or the like, or a stacked film including two or more thereof.

The pad electrode 194 is exposed on a junction surface (the front surface 19S1 of the multilayer wiring layer 19) between the sensor board 10 and the logic board 20. The pad electrode 194 is used, for example, for coupling to the logic board 20. The pad electrode 194 is formed by using, for example, copper (Cu).

It is to be noted that FIG. 6 illustrates an example in which the three wiring layers 191, 192, and 195 are formed in the multilayer wiring layer 19, but the total number of wiring layers in the multilayer wiring layer 19 is not limited.

The logic board 20 includes, for example, a semiconductor substrate 21 and a multilayer wiring layer 22. The semiconductor substrate 21 includes a silicon substrate. The logic board 20 includes logic circuits including a readout circuit, a vertical drive circuit, a column signal processing circuit, a horizontal drive circuit, an output circuit, and the like. The logic circuits output pixel signals based on electric charge outputted from the bias voltage application unit 110 and the unit pixels P in the pixel array unit 100A.

In the multilayer wiring layer 22, a gate wiring line 221 of a transistor included, for example, in the readout circuit and wiring layers 222, 223, 224, and 225 each including one or more wiring lines are stacked in this order from the semiconductor substrate 21 side with an interlayer insulating layer 226 interposed in between. A plurality of pad electrodes 227 is buried in a front surface (a front surface 22S1 of the multilayer wiring layer 22) of the interlayer insulating layer 226 opposite to the semiconductor substrate 21 side. The plurality of pad electrodes 227 is electrically coupled to a portion of the wiring lines in the wiring layer 225 through a via V3.

In addition, FIG. 6 illustrates an example in which a wiring layer (wiring layer 195) that electrically couples the anode electrodes 15 to each other is provided on the sensor board 10 side. The anode electrodes 15 are provided in the plurality of respective unit pixels P. This is not, however, limitative. For example, as illustrated in FIG. 7, there may be provided a wiring layer 228 in the multilayer wiring layer 22. The anode electrodes 15 provided in the plurality of respective unit pixels P may be electrically coupled to each other through the pad electrodes 194 and 227 on the logic board 20 side having a higher degree of wiring freedom than that of the multilayer wiring layer 19. This makes it possible to reduce wiring resistance. In addition, this reduces occurrence of shading caused by an uneven anode potential in the pixel array unit 100A brought about in a case where intense light enters the light-receiving element 12.

As with the interlayer insulating layer 193, the interlayer insulating layer 117 includes, for example, a monolayer film including one of silicon oxide (SiOₓ), TEOS, silicon nitride (SiNₓ), silicon oxynitride (SiOₓN_{y}), or the like, or a stacked film including two or more thereof.

The gate wiring line 221 and the wiring layers 222, 223, 224, 225, and 228 are each formed by using, for example, aluminum (Al), copper (Cu), tungsten (W), or the like as with the wiring layers 191, 192, and 195.

The pad electrode 227 is exposed on the junction surface (the front surface 22S1 of the multilayer wiring layer 22) between the sensor board 10 and the logic board 20. The pad electrode 227 is used, for example, for coupling to the sensor board 10. As with the pad electrode 194, the pad electrode 227 is formed by using, for example, copper (Cu).

In the photodetector 1, for example, a CuCu junction is formed between the pad electrode 194 and the pad electrode 227. This electrically couples the cathode of the light-receiving element 12 to the quenching resistance element 120 provided on the logic board 20 side and electrically couples the anode of the light-receiving element 12 to the bias voltage application unit 110.

For example, there is provided an on-chip lens 33, for example, for each of the unit pixels P on the light-receiving surface (second surface 11S2) side of the semiconductor substrate 11 with a protective layer 31 and a color filter 32 interposed in between.

The on-chip lens 33 condenses light coming from above on the light-receiving element 12. The on-chip lens 33 is formed by using, for example, silicon oxide (SiOₓ) or the like. The anode electrodes 15 provided in the plurality of respective unit pixels P disposed in a matrix are disposed, in a plan view, near boundaries between the on-chip lenses 33 provided in the four respective unit pixels P disposed, for example, in two rows and two columns, for example, as illustrated in FIG. 4.

### 1-2. Workings and Effects

In the photodetector 1 according to the present embodiment, the anode electrodes 15 are each disposed in the oblique (e.g., the 45° direction) direction from the middle of the unit pixel P and the cathode electrodes 16 are each disposed substantially in the middle of the unit pixel P. The anode electrodes 15 are electrically coupled to the light-receiving sections 13 independently in the plurality of respective unit pixels P disposed in an array in the row direction and the column direction. The cathode electrodes 16 are each electrically coupled to the multiplication section 14. The following describes this.

An avalanche photodiode is a SPAD element that multiplies a single electron to several tens of thousands of electrons by having a high electric field applied to a semi-conductor. An electric field of 0.4 to 0.6 MV/cm is applied to the avalanche photodiode, for example, in a case of silicon (Si).

In a typical photodetector in which a plurality of pixels each having a rectangular shape is disposed in an array in the row direction and the column direction, an avalanche photodiode disposed for each of the pixels has a rectangular shape as with the pixel. A cathode (n⁺⁺) is disposed, for example, substantially in the middle of the pixel. Anodes (p⁺⁺) are disposed between the pixels adjacent, for example, in the row direction and the column direction and at four corners of the rectangular shape.

A voltage difference of 20 V to 30 V is applied to an anode (p⁺⁺) and a cathode (n⁺⁺) of an avalanche photodiode in reverse bias. Almost no currents flow before avalanche multiplication. This voltage difference is thus applied to a region (neutral region) other than a p-type and n-type avalanche multiplication region. This voltage difference is applied to a short depletion layer of high-concentration n-type and p-type semi-conductor regions (p⁺/n⁺) included in the avalanche multiplication region to apply a high electric field of 0.4 MV/cm to 0.6 MV/cm. In a case where the avalanche photodiode is miniaturized, each structure is decreased to ¼, for example, to decrease a side of about 10 μm, for example, to a ¼ size (a side of about 2.5 μm).

It is, however, difficult to lower an avalanche electric field of 0.4 MV/cm to 0.6 MV/cm and difficult to lower a voltage difference of 20 V to 30 V. In a case where a size of the avalanche photodiode having a rectangular shape as described above is decreased to ¼, an electric field in a lateral direction grows four times. For example, in a case where an avalanche photodiode having a side of 10 μm has an electric field of 0.1 MV/cm to 0.2 MV/cm in the lateral direction, an avalanche photodiode having a side of 2.5 μm has an electric field of 0.4 MV/cm to 0.8 MV/cm in the lateral direction. This is equal to the avalanche electric field or more. Thus, there is a concern about the occurrence of edge breakdown.

In contrast, in the present embodiment, the anode electrodes 15 are each disposed in the oblique (e.g., the 45° direction) direction from the middle of the unit pixel P and the cathode electrodes 16 are each disposed substantially in the middle of the unit pixel P as described above. The anode electrodes 15 are electrically coupled to the light-receiving sections 13 independently in the plurality of respective unit pixels P disposed in an array in the row direction and the column direction. The cathode electrodes 16 are each electrically coupled to the multiplication section 14. This makes it possible to secure a distance between the anode electrode 15 and the cathode electrode 16 that is √2 times greater than pixel pitch as compared with an avalanche photodiode having a rectangular shape in which anodes (p⁺⁺) are disposed between pixels adjacent in the row direction and the column direction as described above. This makes it possible to make the electric field in the lateral direction smaller, for example, than the avalanche electric field.

As described above, the photodetector 1 according to the present embodiment makes it possible to reduce the occurrence of edge breakdown.

Next, modification examples 1 to 7, application examples, and a practical application example of the present disclosure are described. The following assigns the same signs to components similar to those of the embodiment described above and omits descriptions thereof as appropriate.

### 2. Modification Examples

### 2-1. Modification Example 1

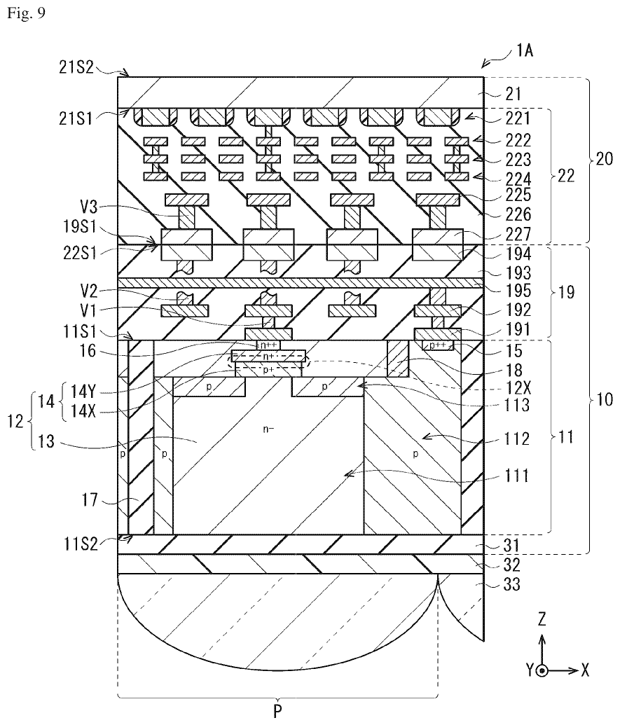

FIG. 8 schematically illustrates a planar configuration of a photodetector (photodetector 1A) according to the modification example 1 of the present disclosure. FIG. 9 schematically illustrates an example of a cross-sectional configuration of the photodetector 1A illustrated in FIG. 8 corresponding to an IV-IV line. For example, as in the embodiment described above, the photodetector 1A is applied to a distance image sensor (distance image apparatus 1000), an image sensor, or the like that measures a distance in the ToF method. The photodetector 1A according to the present modification example further includes an electrode isolation section 18 between the anode electrode 15 and the cathode electrode 16.

The electrode isolation section 18 electrically isolates the anode electrode 15 and the cathode electrode 16. The electrode isolation section 18 is provided, for example, to be continuous to the pixel isolation section 17 and extends the pixel isolation section 17 to between the anode electrode 15 and the cathode electrode 16. The pixel isolation section 17 is provided in an octagonal shape to surround the light-receiving section 13 in a plan view. The electrode isolation section 18 extends from the first surface 11S1 of the semiconductor substrate 11 to a depth at which the electrode isolation section 18 comes into contact with the p-type semiconductor region (p) 112 provided on the side surface of the pixel isolation section 17 corresponding, for example, to the light-receiving section 13. As with the pixel isolation section 17, the electrode isolation section 18 is formed by using, for example, an insulating film such as a silicon oxide (SiOₓ) film.

In this way, the photodetector 1A according to the present modification example includes the electrode isolation section 18 between the anode electrode 15 and the cathode electrode 16. This makes it possible to secure a distance of the semiconductor substrate 11 in a longitudinal direction (Z axis direction) in addition to an in-plane direction (XY plane direction). This makes it possible to make the electric field in the lateral direction further smaller and further reduce the occurrence of edge breakdown.

### 2-2. Modification Example 2

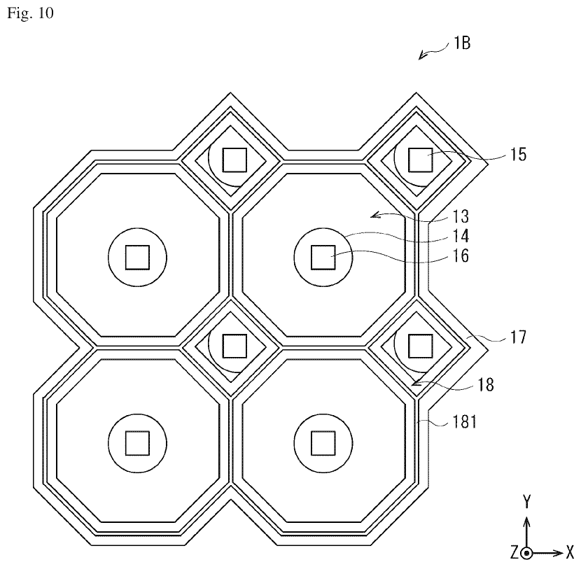

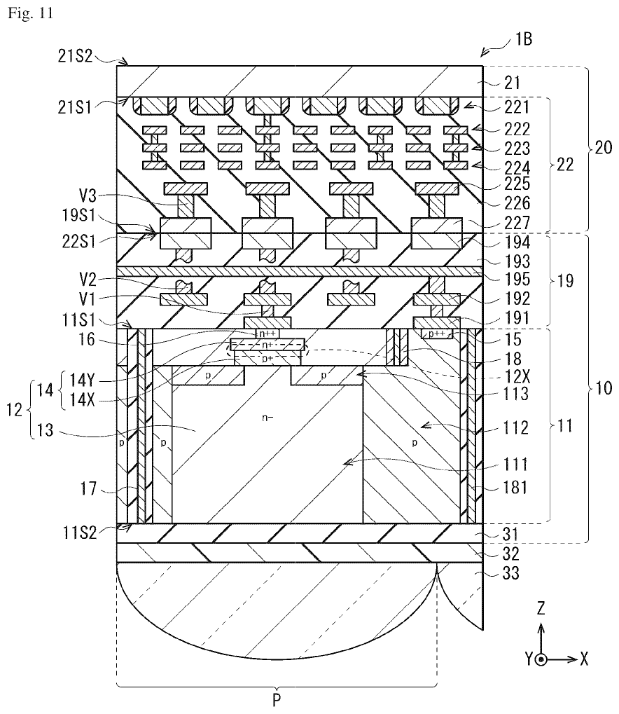

FIG. 10 schematically illustrates a planar configuration of a photodetector (photodetector 1B) according to the modification example 2 of the present disclosure. FIG. 11 schematically illustrates an example of a cross-sectional configuration of the photodetector 1B illustrated in FIG. 10. For example, as in the embodiment described above, the photodetector 1B is applied to a distance image sensor (distance image apparatus 1000), an image sensor, or the like that measures a distance in the ToF method. The photodetector 1B according to the present modification example has an optical reflection film 181 buried in the pixel isolation section 17 and the electrode isolation section 18.

It is possible to form the optical reflection film 181 by using, for example, an electrically conductive material. Among electrically conductive materials, it is preferable to form the optical reflection film 181 by using an electrically conductive material having a light-shielding property. Examples of such a material include tungsten (W), silver (Ag), copper (Cu), aluminum (Al), an alloy of Al and copper (Cu), or the like.

In this way, the photodetector 1B according to the present modification example has the optical reflection film 181 buried in the pixel isolation section 17 and the electrode isolation section 18. This attains an effect of making it possible to suppress crosstalk of oblique incident light between the unit pixels P adjacent in the row direction, the column direction, and the oblique direction in addition to effects according to the embodiment described above.

### 2-3. Modification Example 3

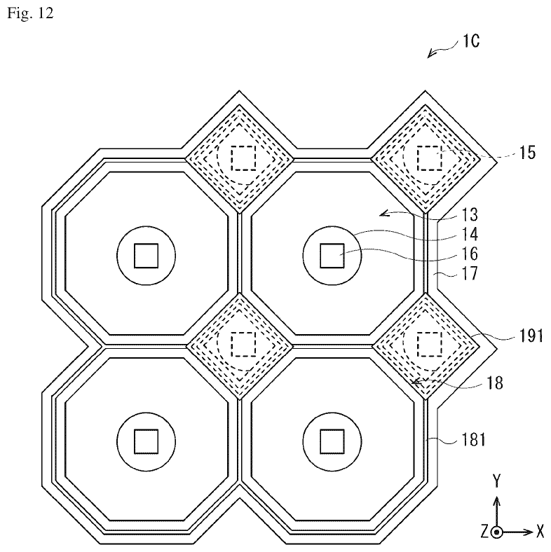

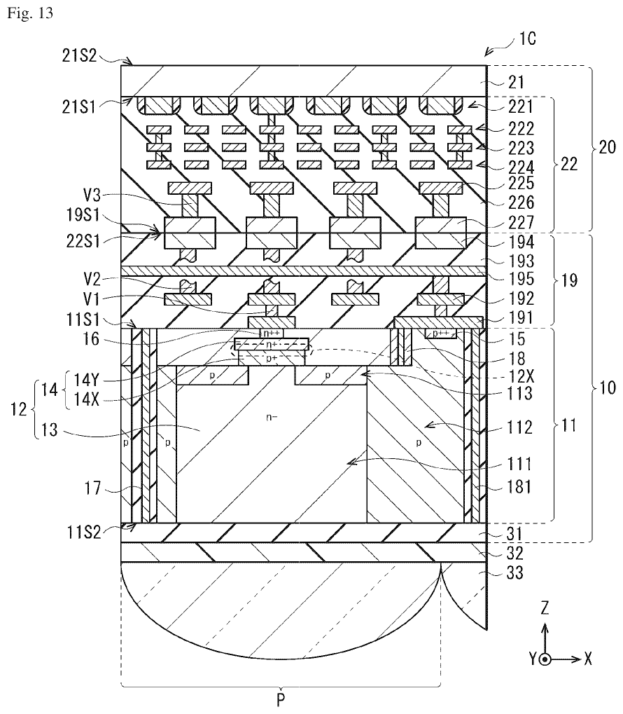

FIG. 12 schematically illustrates a planar configuration of a photodetector (photodetector 1C) according to the modification example 3 of the present disclosure. FIG. 13 schematically illustrates an example of a cross-sectional configuration of the photodetector 1C illustrated in FIG. 12. For example, as in the embodiment described above, the photodetector 1C is applied to a distance image sensor (distance image apparatus 1000), an image sensor, or the like that measures a distance in the ToF method. In the photodetector 1C according to the present modification example, the wiring layer 191 coupled to the anode electrode 15 is enlarged. The optical reflection film 181 provided in the modification example 2 described above is used as an anode wiring line.

In this way, in the photodetector 1C according to the present modification example, the optical reflection film 181 buried in the pixel isolation section 17 and the electrode isolation section 18 is used as an anode wiring line. This attains an effect of making it possible to reduce the wiring resistance as compared with the embodiment described above.

### 2-4. Modification Example 4

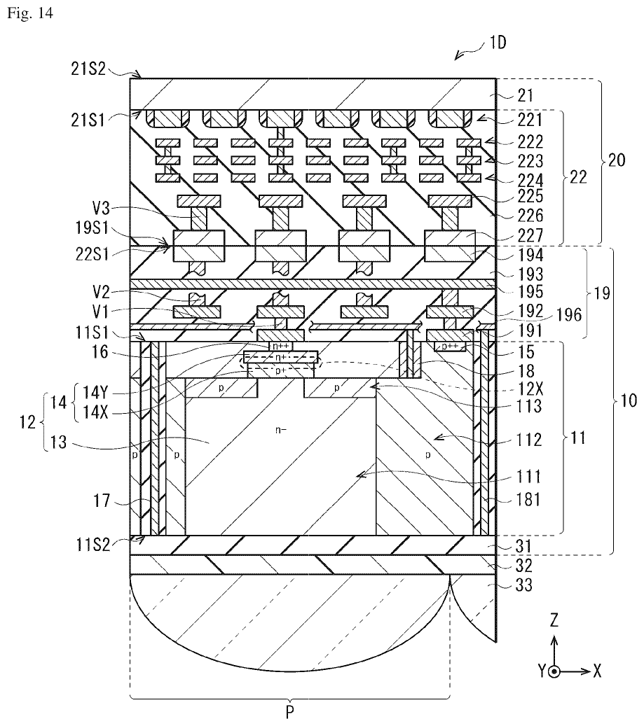

FIG. 14 schematically illustrates an example of a cross-sectional configuration of a photodetector (photodetector 1D) according to the modification example 4 of the present disclosure. For example, as in the embodiment described above, the photodetector 1D is applied to a distance image sensor (distance image apparatus 1000), an image sensor, or the like that measures a distance in the ToF method.

In the modification example 3 described above, the example has been described in which the optical reflection film 181 is used as an anode wiring line, but this is not limitative. A potential (intermediate potential) between the respective potentials to be applied, for example, to the anode electrode 15 and the cathode electrode 16 may be applied to the optical reflection film 181.

In this way, in the photodetector 1D according to the present modification example, the potential (intermediate potential) between the respective potentials to be applied to the anode electrode 15 and the cathode electrode 16 is applied to the optical reflection film 181. This makes it possible to decrease the electric field in the lateral direction as compared with the embodiment described above. It is thus possible to further reduce the occurrence of edge breakdown.

### 2-5. Modification Example 5

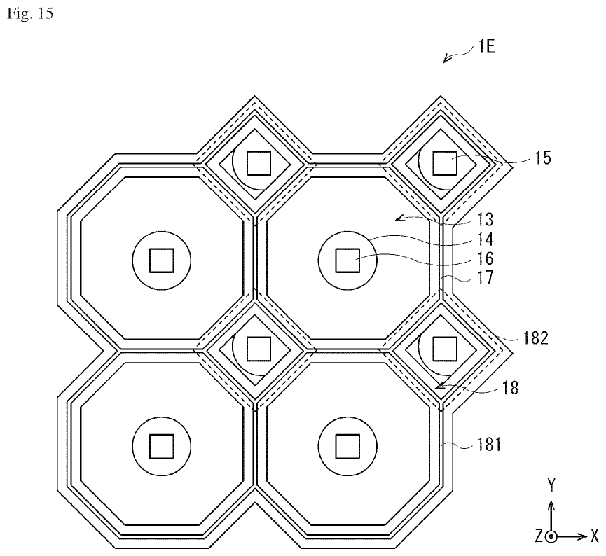

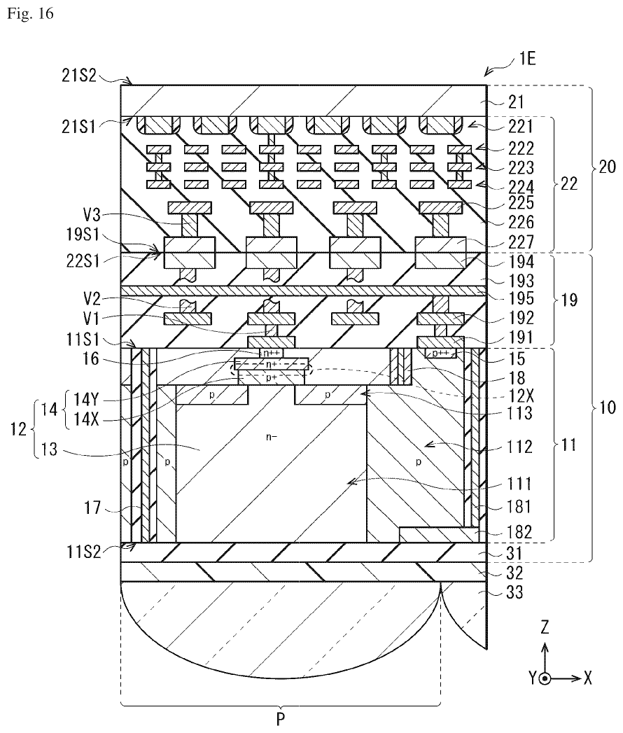

FIG. 15 schematically illustrates a planar configuration of a photodetector (photodetector 1E) according to the modification example 5 of the present disclosure. FIG. 16 schematically illustrates an example of a cross-sectional configuration of the photodetector 1E illustrated in FIG. 15. For example, as in the embodiment described above, the photodetector 1E is applied to a distance image sensor (distance image apparatus 1000), an image sensor, or the like that measures a distance in the ToF method. In the photodetector 1E according to the present modification example, a light-shielding film 182 is formed to be buried in the second surface 11S2 side of the semiconductor substrate 11 to cover the anode electrode 15 in a plan view. The anode electrode 15 is formed to be buried in the first surface 11S1 of the semiconductor substrate 11.

In this way, the photodetector 1E according to the present modification example includes the light-shielding film 182 in the second surface 11S2 of the semiconductor substrate 11 to cause the light-shielding film 182 to be superimposed on the anode electrode 15 in a plan view. This attains an effect of making it possible to suppress crosstalk caused by the anode electrodes 15 protruding to the unit pixels P adjacent in the row direction, the column direction, and the oblique direction, for example, as illustrated in FIGS. 1 and 4 in addition to the effects according to the embodiment described above.

### 2-6. Modification Example 6

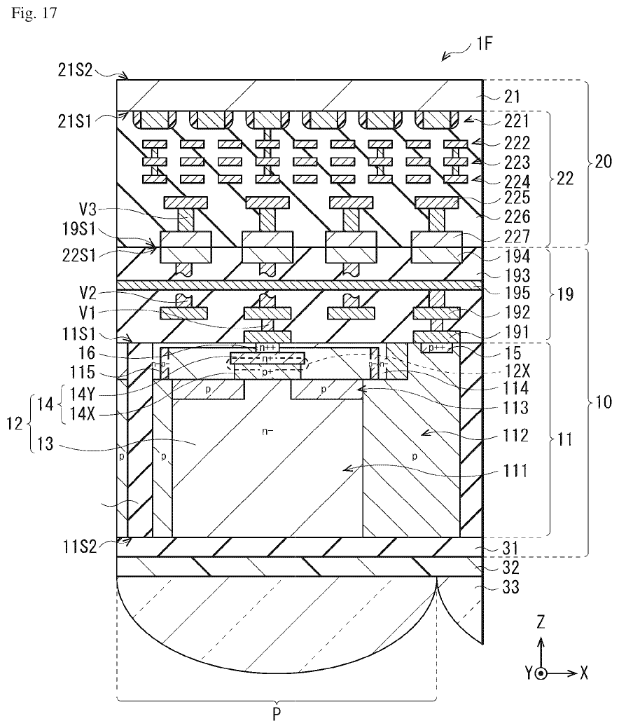

FIG. 17 schematically illustrates an example of a cross-sectional configuration of a photodetector (photodetector 1F) according to the modification example 6 of the present disclosure. For example, as in the embodiment described above, the photodetector 1F is applied to a distance image sensor (distance image apparatus 1000), an image sensor, or the like that measures a distance in the ToF method.

In the embodiment described above, the example has been described in which no p-type semiconductor region (p) is provided on the side surface of the pixel isolation section 17 corresponding to the multiplication section 14, but the p-type semiconductor region (p) 112 is selectively provided on the side surface of the pixel isolation section 17 corresponding to the light-receiving section 13. This is not, however, limitative. There may be provided an n-type semiconductor region (n⁻) 114 and a p-type semiconductor region (p⁻) 115 on the side surfaces of the pixel isolation section 17 and the electrode isolation section 18 corresponding to the multiplication section 14 in this order from the pixel isolation section 17 and electrode isolation section 18 side. The n-type semiconductor region (n⁻) 114 has a lower impurity concentration than that of the n-type semiconductor region (n⁺) 14Y included in the multiplication section 14. The p-type semiconductor region (p⁻) 115 has a lower impurity concentration than that of the p-type semiconductor region (p⁺) 14X included in the multiplication section 14. It is to be noted that the n-type semiconductor region (n⁻) 114 further extends to the first surface 11S1 of the semiconductor substrate 11. The n-type semiconductor region (n⁻) 114 is electrically coupled to the cathode electrode 16.

In this way, the photodetector 1F according to the present modification example includes the n-type semiconductor region (n⁻) 114 and the p-type semiconductor region (p⁻) 115 on the side surfaces of the pixel isolation section 17 and the electrode isolation section 18 corresponding to the multiplication section 14 in this order from the pixel isolation section 17 and electrode isolation section 18 side. This makes it possible to perform pinning on the respective side surfaces of the pixel isolation section 17 and the electrode isolation section 18. It is thus possible to reduce generation of dark currents.

In addition, in the photodetector IF according to the present modification example, the n-type semiconductor region (n⁻) 114 extends to the first surface 11S1 of the semiconductor substrate 11. The n-type semiconductor region (n⁻) 114 is electrically coupled to the cathode electrode 16. This makes it possible to discharge the dark currents generated on the respective side surfaces the pixel isolation section 17 and the electrode isolation section 18 from the cathode electrode 16 without having the dark currents through the multiplication section 14.

### 2-7. Modification Example 7

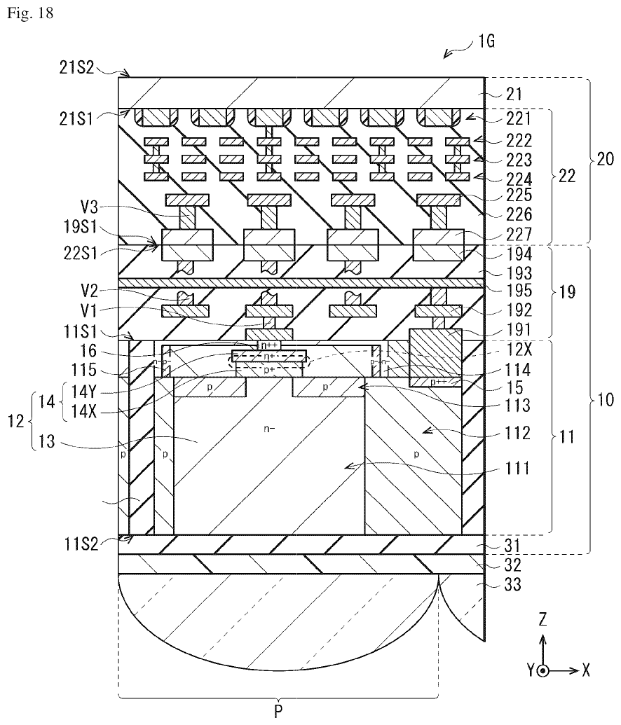

FIG. 18 schematically illustrates an example of a cross-sectional configuration of a photodetector (photodetector 1G) according to the modification example 7 of the present disclosure. For example, as in the embodiment described above, the photodetector 1G is applied to a distance image sensor (distance image apparatus 1000), an image sensor, or the like that measures a distance in the ToF method.

In the embodiment or the like described above, the example has been described in which the anode electrode 15 including a p-type semiconductor region (p⁺⁺) is provided, but an electrically conducive film (e.g., the wiring layer 191) such as a metal film may be buried in the first surface 11S1 of the semiconductor substrate 11, for example, as illustrated in FIG. 18 and this may be used as the anode electrode 15. This makes it possible to reduce resistance as compared with the anode electrode 15 including a p-type semiconductor region (p⁺⁺) as in the embodiment described above.

### 3. Application Examples

### Application Example 1

FIG. 19 illustrates an example of a schematic configuration of the distance image apparatus 1000 that serves as an electronic apparatus including the photodetector (e.g., the photodetector 1) according to any of the embodiment and the modification examples 1 to 7 described above. This distance image apparatus 1000 corresponds to a specific example of a “distance measurement apparatus” according to an embodiment of the present disclosure.

The distance image apparatus 1000 includes, for example, a light source device 1100, an optical system 1200, the photodetector 1, an image processing circuit 1300, a monitor 1400, and a memory 1500.

The distance image apparatus 1000 receives light (modulated light or pulsed light) projected onto an irradiation target 2000 from the light source device 1100 and reflected on a surface of the irradiation target 2000. This allows the distance image apparatus 1000 to acquire a distance image corresponding to a distance to the irradiation target 2000.

The optical system 1200 includes one or more lenses. The optical system 1200 guides image light (incident light) from the irradiation target 2000 to the photodetector 1 and forms an image on a light-receiving surface (sensor section) of the photodetector 1.

The image processing circuit 1300 performs image processing for constructing a distance image on the basis of a distance signal supplied from the photodetector 1. The distance image (image data) resulting from the image processing is supplied to the monitor 1400 for display or supplied to the memory 1500 for storage (recording).

The application of the photodetector (e.g., the photodetector 1) described above allows the distance image apparatus 1000 configured in this way to calculate the distance to the irradiation target 2000 on the basis of only a light reception signal from the highly stable unit pixel P and generate a distance image having high accuracy. In other words, the distance image apparatus 1000 makes it possible to acquire a more accurate distance image.

### Application Example 2

In addition, a photodetector (e.g., the photodetector 1) as described above is applicable, for example, to various kinds of electronic apparatuses (e.g., an imaging apparatus 3000) including an imaging system such as a digital still camera or a digital video camera, a mobile phone having an imaging function, or another apparatus having an imaging function.

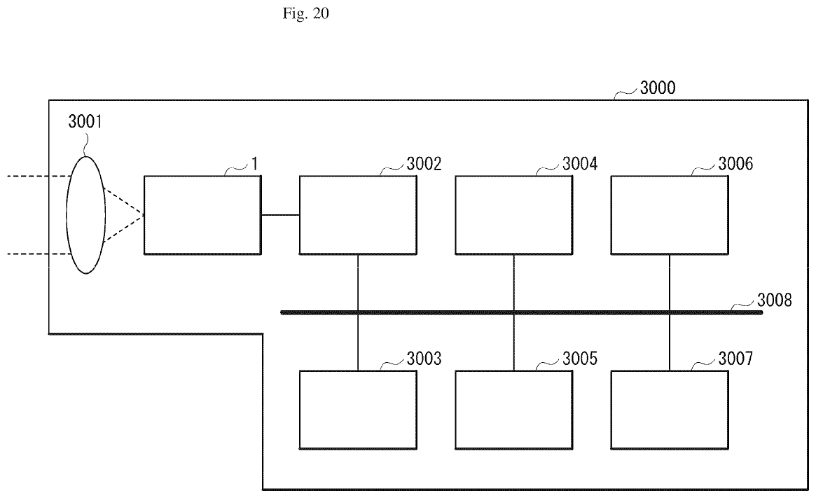

FIG. 20 is a block diagram illustrating an example of a configuration of the imaging apparatus 3000.

As illustrated in FIG. 20, the imaging apparatus 3000 includes an optical system 3001, the photodetector 1, and a Digital Signal Processor (DSP) 3002. The DSP 3002, a memory 3003, a display device 3004, a recording device 3005, an operation system 3006, and a power supply system 3007 are coupled through a bus 3008. The imaging apparatus 3000 makes it possible to capture a still image and a moving image.

The optical system 3001 includes one or more lenses. The optical system 3001 takes in incident light (image light) from an object and forms an image on an imaging surface of the photodetector 1.

As the photodetector 1, the photodetector 1 described above is applied. The photodetector 1 converts the amount of incident light whose image is formed on the imaging surface by the optical system 3001 into electric signals in units of pixels. The photodetector 1 supplies the electric signals to the DSP 3002.

The DSP 3002 performs various kinds of signal processing on a signal from the photodetector 1 to acquire an image. The DSP 3002 causes the memory 3003 to temporarily store data of the image. The data of the image stored in the memory 3003 is recorded in the recording device 3005. Alternatively, the data of the image stored in the memory 3003 is supplied to the display device 3004 to cause the image to be displayed. In addition, the operation system 3006 receives a variety of operations made by a user and supplies operation signals to respective blocks of the imaging apparatus 3000. The power supply system 3007 supplies power to drive the respective blocks of the imaging apparatus 3000.

### 4. Practical Application Example

### Example of Practical Application to Mobile Body

The technology according to an embodiment of the present disclosure is applicable to a variety of products. For example, the technology according to an embodiment of the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

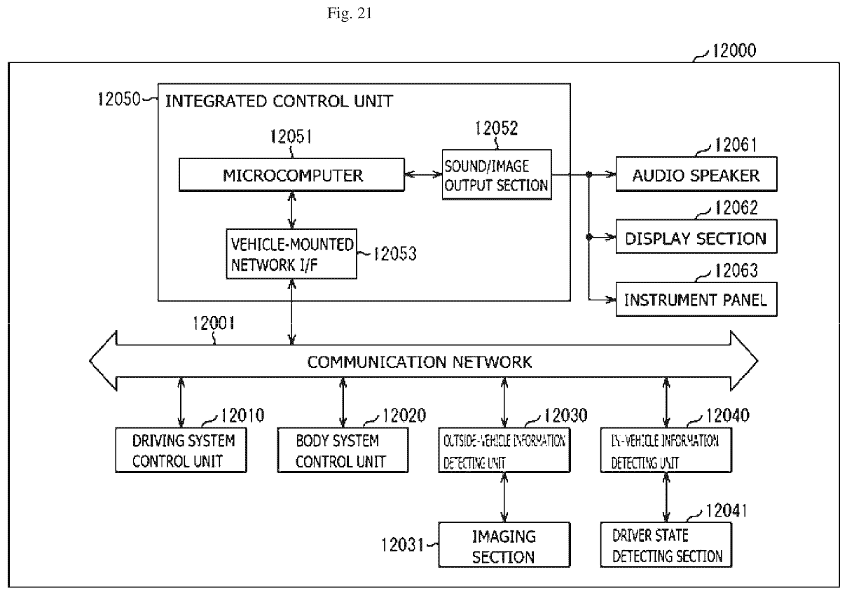

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

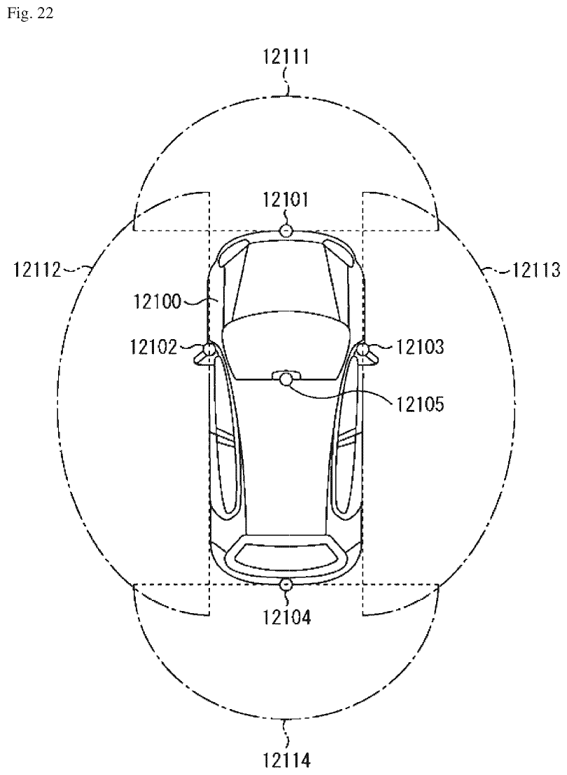

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from photodetectors 1 included in the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given above with reference to the embodiment, the modification examples 1 to 7, the application examples, and the practical application example, the contents of an embodiment of the present disclosure are not limited to the embodiment and the like described above. A variety of modifications are possible. For example, the photodetector according to an embodiment of the present disclosure does not have to include all the respective components described in the embodiment or the like described above. Meanwhile, the photodetector may include another layer. For example, in a case where the photodetector 1 detects light (e.g., near-infrared light (IR)) other than visible light, the color filter 32 may be omitted.

In addition, polarity of a semiconductor region included in the photodetector according to an embodiment of the present disclosure may be reversed. Further, the photodetector according to an embodiment of the present disclosure may use holes as signal charge.

Still further, the photodetector according to an embodiment of the present disclosure may have any potentials as long as it is possible to bring about avalanche multi-plication by applying a reverse bias between the anode and the cathode.

In addition, in the embodiment or the like described above, the example has been described in which silicon is used as the semiconductor substrate 11, but it is also possible to use, for example, germanium (Ge) or a compound semiconductor (e.g., silicon germanium (SiGe)) of silicon (Si) and germanium (Ge) as the semiconductor substrate 11.

Further, in the embodiment or the like described above, the unit pixel P having an octagonal shape has been described as an example, but a shape of the unit pixel P is not limited to this. The unit pixel P may have a rectangular shape, a pentagonal shape, or a hexagonal shape. In addition, the unit pixel P may have a circular shape. Whichever shape the unit pixels P each have, the anode electrode 15 is disposed in the gap between the unit pixels P adjacent in the oblique direction.

It is to be noted that the effects described in the embodiment or the like described above are merely examples. The effects described in the embodiment or the like described above may be other effects or may further include other effects.

It should be understood by those skilled in the art that various modifications, combinations, sub-combinations, and alterations may occur depending on design requirements and other factors insofar as they are within the scope of the appended claims or the equivalents thereof.

It is to be noted that an embodiment of the present disclosure may have the following configurations. According to an embodiment of the present technology having the following configurations, in each of the plurality of pixels disposed in the array in the row direction and the column direction, the first electrode is disposed in the oblique direction from the middle of the pixel on the first surface side of the semiconductor substrate and the second electrode is disposed substantially in the middle of the pixel on the first surface side of the semiconductor substrate. The first electrode is electrically coupled to the light-receiving section. The second electrode is electrically coupled to the multiplication section. This secures a distance between the first electrode and the second electrode. This makes the electric field in the lateral direction smaller and makes it possible to reduce the occurrence of edge breakdown.
(A1)

A photodetector including:
a semiconductor substrate having a first surface and a second surface that are opposed to each other, the semiconductor substrate including a pixel array unit in which a plurality of pixels is disposed in an array in a row direction and a column direction;
a light-receiving section that is provided in the semiconductor substrate for each of the pixels, the light-receiving section generating a carrier through photoelectric conversion, the carrier corresponding to an amount of received light;
a multiplication section including a first semiconductor region and a second semiconductor region that are stacked on the first surface side of the semiconductor substrate for each of the pixels, the first semiconductor region having a first electrical conduction type, the second semiconductor region having a second electrical conduction type different from the first electrical conduction type, the multiplication section subjecting the carrier generated by the light-receiving section to avalanche multiplication;
a first electrode that is disposed for each of the pixels in an oblique direction from a middle of the pixel on the first surface side of the semiconductor substrate, the first electrode being electrically coupled to the light-receiving section independently for each of the pixels; and
a second electrode that is disposed for each of the pixels substantially in the middle of the pixel on the first surface side of the semiconductor substrate, the second electrode being electrically coupled to the multiplication section independently for each of the pixels.
(A2)

The photodetector according to (A1), in which each of the pixels has a polygonal shape or a circular shape and the first electrode is disposed between the pixels adjacent in the oblique direction.
(A3)

The photodetector according to (A1) or (A2), in which each of the pixels has an octagonal shape and the first electrode is disposed in a gap between the pixels adjacent in the oblique direction.
(A4)

The photodetector according to any one of (A1) to (A3), in which the first electrodes in the plurality of pixels disposed in the array in the row direction and the column direction are each disposed between the second electrodes provided in the plurality of respective pixels adjacent in the oblique direction.
(A5)

The photodetector according to any one of (A1) to (A4), in which a distance between the first electrodes provided in the plurality of respective pixels adjacent in the oblique direction and a distance between the second electrodes provided in the plurality of respective pixels adjacent in the oblique direction are equal to each other in the plurality of pixels disposed in the array in the row direction and the column direction.
(A6)

The photodetector according to any one of (A1) to (A5), in which a distance between the first electrodes provided in the plurality of respective pixels adjacent in the row direction and the column direction and a distance between the second electrodes provided in the plurality of respective pixels adjacent in the row direction and the column direction are equal to each other.
(A7)

The photodetector according to any one of (A1) to (A6), further including a pixel isolation section that is provided around each of the plurality of pixels to extend between the first surface and the second surface of the semiconductor substrate, the pixel isolation section electrically isolating the plurality of adjacent pixels.
(A8)

The photodetector according to (A7), further including an electrode isolation section that is provided on the first surface side, the electrode isolation section electrically isolating the first electrode and the second electrode, in which the electrode isolation section is continuous to the pixel isolation section.
(A9)

The photodetector according to (A8), in which the pixel isolation section and the electrode isolation section are each formed by using an insulating film.
(A10)

The photodetector according to (A9), in which an optical reflection film is buried in the pixel isolation section and the electrode isolation section.
(A11)

The photodetector according to (A10), in which the optical reflection film is formed by using an electrically conductive material.
(A12)

The photodetector according to (A11), in which the optical reflection film further serves as a wiring line of the first electrode.
(A13)

The photodetector according to (A11), in which a potential between respective potentials to be applied to the first electrode and the second electrode is applied to the optical reflection film.
(A14)

The photodetector according to any one of (A1) to (A13), in which a light-shielding film is formed on the second surface of the semiconductor substrate to cover the first electrode in a plan view, the first electrode being provided on the first surface of the semiconductor substrate.
(A15)

The photodetector according to any one of (A7) to (A14), in which a third semiconductor region having the first electrical conduction type is provided on a side surface of the pixel isolation section corresponding to the light-receiving section, the third semiconductor region having a lower impurity concentration than an impurity concentration of the first semiconductor region, and
a fourth semiconductor region having the second electrical conduction type and a fifth semiconductor region having the first electrical conduction type are provided on a side surface of the pixel isolation section corresponding to the multiplication section in this order from the pixel isolation section side, the fourth semiconductor region having a lower impurity concentration than an impurity concentration of the second semiconductor region, the fifth semiconductor region having a lower impurity concentration than the impurity concentration of the third semiconductor region.
(A16)

The photodetector according to (A15), in which the fourth semiconductor region further extends to the first surface of the semiconductor substrate and the fourth semiconductor region is electrically coupled to the second electrode.
(A17)

The photodetector according to any one of (A1) to (A16), in which the first electrode includes an impurity region or an electrically conducive film that is formed to be buried in the first surface of the semiconductor substrate, and the second electrode includes an impurity region that is formed to be buried in the first surface of the semiconductor substrate.
(A18)

A distance measurement apparatus including:
an optical system;
a photodetector; and
a signal processing circuit that calculates a distance to a measurement target from an output signal of the photodetector, in which
the photodetector includes
a semiconductor substrate having a first surface and a second surface that are opposed to each other, the semiconductor substrate including a pixel array unit in which a plurality of pixels is disposed in an array in a row direction and a column direction,
a light-receiving section that is provided in the semiconductor substrate for each of the pixels, the light-receiving section generating a carrier through photoelectric conversion, the carrier corresponding to an amount of received light,
a multiplication section including a first semiconductor region and a second semiconductor region that are stacked on the first surface side of the semiconductor substrate for each of the pixels, the first semiconductor region having a first electrical conduction type, the second semiconductor region having a second electrical conduction type different from the first electrical conduction type, the multiplication section subjecting the carrier generated by the light-receiving section to avalanche multiplication,
a first electrode that is disposed for each of the pixels in an oblique direction from a middle of the pixel on the first surface side of the semiconductor substrate, the first electrode being electrically coupled to the light-receiving section independently for each of the pixels, and
a second electrode that is disposed for each of the pixels substantially in the middle of the pixel on the first surface side of the semiconductor substrate, the second electrode being electrically coupled to the multiplication section independently for each of the pixels.
(A19)

An imaging apparatus including
a photodetector, in which
the photodetector includes
a semiconductor substrate having a first surface and a second surface that are opposed to each other, the semiconductor substrate including a pixel array unit in which a plurality of pixels is disposed in an array in a row direction and a column direction,
a light-receiving section that is provided in the semiconductor substrate for each of the pixels, the light-receiving section generating a carrier through photoelectric conversion, the carrier corresponding to an amount of received light,
a multiplication section including a first semiconductor region and a second semiconductor region that are stacked on the first surface side of the semiconductor substrate for each of the pixels, the first semiconductor region having a first electrical conduction type, the second semiconductor region having a second electrical conduction type different from the first electrical conduction type, the multiplication section subjecting the carrier generated by the light-receiving section to avalanche multiplication,
a first electrode that is disposed for each of the pixels in an oblique direction from a middle of the pixel on the first surface side of the semiconductor substrate, the first electrode being electrically coupled to the light-receiving section independently for each of the pixels, and
a second electrode that is disposed for each of the pixels substantially in the middle of the pixel on the first surface side of the semiconductor substrate, the second electrode being electrically coupled to the multiplication section independently for each of the pixels.
(B1)

A photodetector, comprising:
a pixel array, wherein the pixel array includes a plurality of unit pixels, and wherein, in a plan view, the unit pixels are disposed in a plurality of rows and a plurality of columns;
a semiconductor substrate;
a pixel isolation section, wherein the pixel isolation section is disposed in the semiconductor substrate, wherein the pixel isolation section surrounds the unit pixels in the plan view, and wherein a first unit pixel in the plurality of unit pixels includes:
a light receiving section, wherein the light receiving section is disposed within an area formed by the pixel isolation section surrounding the first unit pixel in the plan view, and wherein the light receiving section is disposed in the semiconductor substrate;
a first electrode, wherein the first electrode is disposed within the area formed by the pixel isolation section surrounding the first unit pixel in the plan view; and
a second electrode, wherein the second electrode is disposed within an area of the light receiving section of the first unit pixel in the plan view, and wherein the first electrode and the second electrode are disposed along a line that is oblique relative to the rows and columns of the pixel array.
(B2)

The photodetector of (B1), wherein the light receiving section has an octagonal shape.
(B3)

The photodetector of (B1) or (B2), wherein a third electrode is disposed along the line that is oblique relative to the rows and columns of the pixel array along which the first electrode and the second electrode are also disposed, and wherein the first electrode is disposed between the second electrode and the third electrode.
(B4)

The photodetector of (B3), wherein a distance between the first electrode and the second electrode is equal to a distance between the first electrode and the third electrode.
(B5)

The photodetector of any one of (B1) to (B4), wherein the pixel isolation section extends between a first surface and a second surface of the semiconductor substrate.
(B6)

The photodetector of any one of (B1) to (B5), wherein an electrode isolation section is disposed between the first electrode and the second electrode.
(B7)

The photodetector of (B6), wherein the pixel isolation section and the electrode isolation section include an insulating film.
(B8)

The photodetector of (B6), wherein the pixel isolation section and the electrode isolation section include an optical reflection film disposed between insulating films.
(B9)

The photodetector of (B8), wherein the optical reflection film includes an electrically conductive material.
(B10)

The photodetector of (B8) or (B9), wherein the optical reflection film is electrically connected to the first electrode.
(B11)

The photodetector of any one of (B8) to (B10), wherein an electrical potential applied to the optical reflection film is between an electrical potential applied to the first electrode and an electrical potential applied to the second electrode.
(B12)

The photodetector of any one of (B6) to (B11), wherein the pixel isolation section is connected to the electrode isolation section.
(B13)

The photodetector of any one of (B1) to (B12), wherein a light-shielding film is disposed on the first electrode.
(B14)

The photodetector of any one of (B1) to (B13), further comprising:
a multiplication region, wherein the multiplication region includes a first semiconductor region having a first electrical conduction type and a second semiconductor region having a second electrical conduction type, and wherein the multiplication region is disposed within an area of the light receiving section of the first unit pixel.
(B15)

The photodetector of (B14), further comprising:
a third semiconductor region having the first electrical conduction type, wherein the third semiconductor region is disposed on a side surface of the pixel isolation section adjacent to the light receiving section of the first unit pixel.
(B16)

The photodetector of (B15), further comprising:
a fourth semiconductor region having the first electrical conduction type; and
a fifth semiconductor region having the second electrical conduction type, wherein the fourth and fifth semiconductor regions are disposed on the side surface of the pixel isolation section adjacent to the multiplication region.
(B17)

The photodetector of (B16), wherein the fifth semiconductor region is connected to the second electrode.
(B18)

The photodetector of any one of (B6) to (B12), wherein the light receiving section has an octagonal shape.
(B19)

The photodetector of any one of (B6) to (B12), wherein the pixel isolation section extends between a first surface and a second surface of the semiconductor substrate, and wherein the electrode isolation section extends from the first surface of the semiconductor substrate to a first depth within the semiconductor substrate.
(B20)

A distance measurement apparatus, comprising:
a light source device, wherein the light source device is operable to project light;
an optical system, wherein the optical system is operable to collect light projected from the light source device and reflected from a target;
a photodetector, including:
a pixel array, wherein the pixel array includes a plurality of unit pixels, wherein, in a plan view, the unit pixels are disposed in a plurality of rows and a plurality of columns, and wherein the optical system guides the collected light to the pixel array;
a semiconductor substrate;
a pixel isolation section, wherein the pixel isolation section is disposed in the semiconductor substrate, wherein the pixel isolation section surrounds the unit pixels in a plan view, and wherein a first unit pixel in the plurality of unit pixels includes:
a light receiving section, wherein the light receiving section is disposed within an area formed by the pixel isolation section surrounding the first unit pixel in the plan view, and wherein the light receiving section is disposed in the semiconductor substrate;
a first electrode, wherein the first electrode is disposed within the area formed by the pixel isolation section surrounding the first unit pixel in the plan view; and
a second electrode, wherein the second electrode is disposed within an area of the light receiving section of the first unit pixel in the plan view, and wherein the first electrode and the second electrode are disposed along a line that is oblique relative to the rows and columns of the pixel array; and
an image processing circuit, wherein the image processing circuit is operable to construct a distance image based on a distance signal supplied from the photodetector.

### REFERENCE SIGNS LIST

1, 1A, 1B, 1C, 1D, 1E, IF, 1G photodetector
10 sensor board
11 semiconductor substrate
12 light-receiving element
12X avalanche multiplication region
13 light-receiving section
14 multiplication section
14X p-type semiconductor region (p⁺)
14Y n-type semiconductor region (n⁺)
15 anode electrode
16 cathode electrode
17 pixel isolation section
18 electrode isolation section
19, 22 multilayer wiring layer
20 logic board
31 protective layer
32 color filter
33 on-chip lens
100A pixel array unit
1000 distance image apparatus

What is claimed is:

1. A photodetector, comprising:
a pixel array, wherein the pixel array includes a plurality of unit pixels, and wherein, in a plan view, the unit pixels are disposed in a plurality of rows and a plurality of columns;
a semiconductor substrate;
a pixel isolation section, wherein the pixel isolation section is disposed in the semiconductor substrate, wherein the pixel isolation section surrounds the unit pixels in the plan view, and wherein a first unit pixel in the plurality of unit pixels includes:
a light receiving section, wherein the light receiving section is disposed within an area formed by the pixel isolation section surrounding the first unit pixel in the plan view, and wherein the light receiving section is disposed in the semiconductor substrate;
a first electrode, wherein the first electrode is disposed within the area formed by the pixel isolation section surrounding the first unit pixel in the plan view; and
a second electrode, wherein the second electrode is disposed within an area of the light receiving section of the first unit pixel in the plan view, and wherein the first electrode and the second electrode are disposed along a line that is oblique relative to the rows and columns of the pixel array.

2. The photodetector of claim 1, wherein the light receiving section has an octagonal shape.

3. The photodetector of claim 1, wherein a third electrode is disposed along the line that is oblique relative to the rows and columns of the pixel array along which the first electrode and the second electrode are also disposed, and wherein the first electrode is disposed between the second electrode and the third electrode.

4. The photodetector of claim 3, wherein a distance between the first electrode and the second electrode is equal to a distance between the first electrode and the third electrode.

5. The photodetector of claim 1, wherein the pixel isolation section extends between a first surface and a second surface of the semiconductor substrate.

6. The photodetector of claim 1, wherein an electrode isolation section is disposed between the first electrode and the second electrode.

7. The photodetector of claim 6, wherein the pixel isolation section and the electrode isolation section include an insulating film.

8. The photodetector of claim 6, wherein the pixel isolation section and the electrode isolation section include an optical reflection film disposed between insulating films.

9. The photodetector of claim 8, wherein the optical reflection film includes an electrically conductive material.

10. The photodetector of claim 8, wherein the optical reflection film is electrically connected to the first electrode.

11. The photodetector of claim 8, wherein an electrical potential applied to the optical reflection film is between an electrical potential applied to the first electrode and an electrical potential applied to the second electrode.

12. The photodetector of claim 6, wherein the pixel isolation section is connected to the electrode isolation section.

13. The photodetector of claim 1, wherein a light-shielding film is disposed on the first electrode.

14. The photodetector of claim 1, further comprising:
a multiplication region, wherein the multiplication region includes a first semiconductor region having a first electrical conduction type and a second semiconductor region having a second electrical conduction type, and wherein the multiplication region is disposed within an area of the light receiving section of the first unit pixel.

15. The photodetector of claim 14, further comprising:
a third semiconductor region having the first electrical conduction type, wherein the third semiconductor region is disposed on a side surface of the pixel isolation section adjacent to the light receiving section of the first unit pixel.

16. The photodetector of claim 15, further comprising:
a fourth semiconductor region having the first electrical conduction type; and
a fifth semiconductor region having the second electrical conduction type, wherein the fourth and fifth semiconductor regions are disposed on the side surface of the pixel isolation section adjacent to the multiplication region.

17. The photodetector of claim 16, wherein the fifth semiconductor region is connected to the second electrode.

18. The photodetector of claim 6, wherein the light receiving section has an octagonal shape.

19. The photodetector of claim 6, wherein the pixel isolation section extends between a first surface and a second surface of the semiconductor substrate, and wherein the electrode isolation section extends from the first surface of the semiconductor substrate to a first depth within the semiconductor substrate.

20. A distance measurement apparatus, comprising:
a light source device, wherein the light source device is operable to project light;
an optical system, wherein the optical system is operable to collect light projected from the light source device and reflected from a target;
a photodetector, including:
a pixel array, wherein the pixel array includes a plurality of unit pixels, wherein, in a plan view, the unit pixels are disposed in a plurality of rows and a plurality of columns, and wherein the optical system guides the collected light to the pixel array;
a semiconductor substrate;
a pixel isolation section, wherein the pixel isolation section is disposed in the semiconductor substrate, wherein the pixel isolation section surrounds the unit pixels in a plan view, and wherein a first unit pixel in the plurality of unit pixels includes:
a light receiving section, wherein the light receiving section is disposed within an area formed by the pixel isolation section surrounding the first unit pixel in the plan view, and wherein the light receiving section is disposed in the semiconductor substrate;
a first electrode, wherein the first electrode is disposed within the area formed by the pixel isolation section surrounding the first unit pixel in the plan view; and
a second electrode, wherein the second electrode is disposed within an area of the light receiving section of the first unit pixel in the plan view, and wherein the first electrode and the second electrode are disposed along a line that is oblique relative to the rows and columns of the pixel array; and
an image processing circuit, wherein the image processing circuit is operable to construct a distance image based on a distance signal supplied from the photodetector.
